(19) United States
(12) Patent Application Publication
(10) Pub. No.: US 2003/0116762 A1
(43) Pub. Date: Jun. 26, 2003

(54) Single-chip structure of silicon germanium photodetector and high-speed transistor

(75) Inventors: Hann-Ping Hwang, Hsin-Chu City (TW); Shing-Chii Lu, Hsin-Chu Hsien (TW)

Correspondence Address: BACON & THOMAS, PLLC, 625 SLATERS LANE, FOURTH FLOOR, ALEXANDRIA, VA, 22314

(73) Assignee: Industrial Technology Research, Hsin-Chu Hsien (TW)

(21) Appl. No.: 10/022,349

(22) Filed: Dec. 20, 2001

(51) Int. Cl. H01L 29/06

(52) U.S. Cl. 257/20

(57) ABSTRACT

This invention mainly provides a single-chip structure of silicon-germanium (SiGe) photodetectors and high-speed transistors. Primarily inserting a specified photo-absorbing layer in the photodetector, this device structure then provides the capability to absorb the light spectrum with an infrared wavelength, but also improves the overall optical absorption efficiency indeed. Then consider both the photodetector and the high-speed transistor have similar structures, therefore they can be well integrated on the same substrate by using the single-chip technology. Furthermore, one separated insulation layer will be adopted to isolate the photo-detecting zone and the high-speed transistor zone. Consequently, a single-chip structure of the SiGe photodetector and the high-speed transistor will be implemented.

### BACKGROUND OF INVENTION

1. Field of Invention

This invention mainly provides a single-chip structure of silicon-germanium (SiGe) photodetectors and high-speed transistors. Consider both photodetectors and high-speed transistors have similar device structures; they therefore can be implemented on the same substrate by using single-chip technology. Moreover, one more separated insulation layer will be adopted to isolate the photo-detecting zone and the high-speed transistor zone distinctly. Consequently, a single-chip structure of SiGe photodetectors and high-speed transistors will be implemented.

2. Description of The Prior Art

In fact, the Si-based technology of implementing the high-speed SiGe heterojunction bipolar transistor (SiGe HBT) is well done nowadays, and is sequentially applied to produce the 40 Gb/s opto-electronic integrated circuits (OEICs). However, implementation of photodetector on Si-based substrate is suitable only for the optical receiver with 0.8 μm wavelength band. Today the most popular 1.3 μm and 1.55 μm wavelength bands are used in optical communication system specially, but the photodetector has still adopted the InGaAs photodiode dominantly. Furthermore, the absorption efficiency of the silicon material is very low in these bands, but also not satisfied to implement a system-on-chip (SOC) on the silicon substrate. The best way to build monolithic integrated circuits (ICs) on the silicon substrate with aforesaid band's applications is applying a SiGe/Si multiple-quantum-well (SiGe/Si MQW) structure to make the photodetectors as required.

The traditional SiGe MQW photodiodes have some disadvantages such as no amplification, needing extra 1 μm thickness of the MQW layers, and requiring the waveguide and resonant structures to improve the photo absorption efficiency that is beyond 1.3 μm wavelength bands. Furthermore, the MQW photodiode can't share the compatible fabrication process with the high-speed SiGe HBT. The benefit for integration and the reduction of production cost are relatively bad even if we apply some more special-etching and high-temperature processes. Therefore a designed SiGe/Si MQW phototransistor performs an amplification for absorbing 1.3 μm and/or higher wavelength band light and has the similar fabrication process with the high-speed SiGe HBT is invented to integrate them in the single-chip (monolithic) ICs. And the traditional SiGe photodiode can be continuously used for absorbing the shorter wavelength band (0.7 μm˜1.0 μm) light.

### SUMMARY OF THE INVENTION

Conclusively, the main purpose of this invention is led to solve the aforementioned defects. To overcome those aforesaid defects, this invention achieves a single-chip structure of SiGe photodetectors and high-speed transistors. Consequently, the photodetectors and the high-speed transistors can be monolithically implemented on the same substrate.

Another contribution of this invention is to tremendously reduce the production cost and to maintain the primary device performances in the optic-communication integrated circuits (ICs) based on a single-chip structure of SiGe photodetectors and high-speed transistors.

### BRIEF DESCRIPTION OF THE DRAWINGS

FIG. 1 is a process flowchart of a single-chip structure of SiGe photodetectors and high-speed transistors.

FIGS. 2a, 2b, 2c, 2d, 2e, and 2f are manufacturing process profiles of the first implementation example of a single-chip structure of phototransistors and high-speed bipolar transistors.

FIG. 3 is a structure profile of the second implementation example of a single-chip structure of photodiodes and high-speed bipolar transistors.

### DETAILED DESCRIPTION OF THE PREFERRED EMBODIMENTS

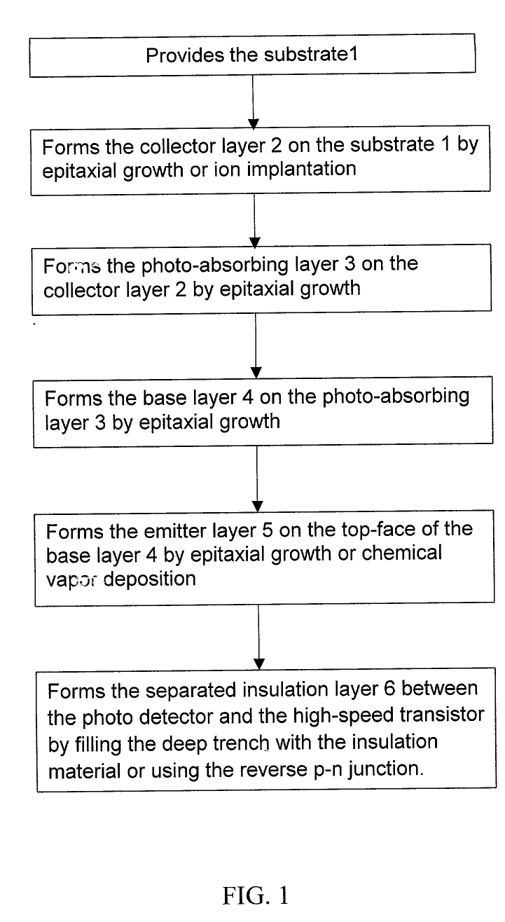

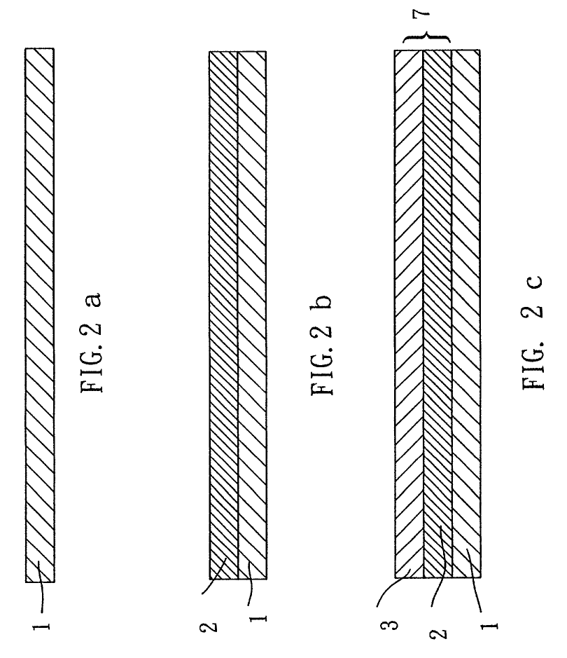

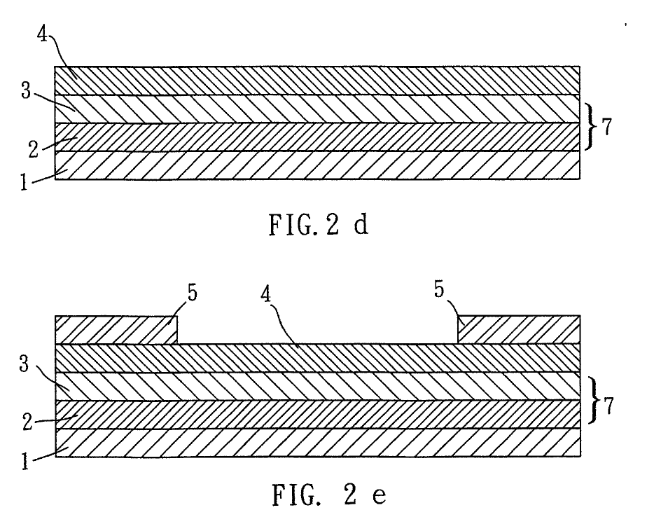

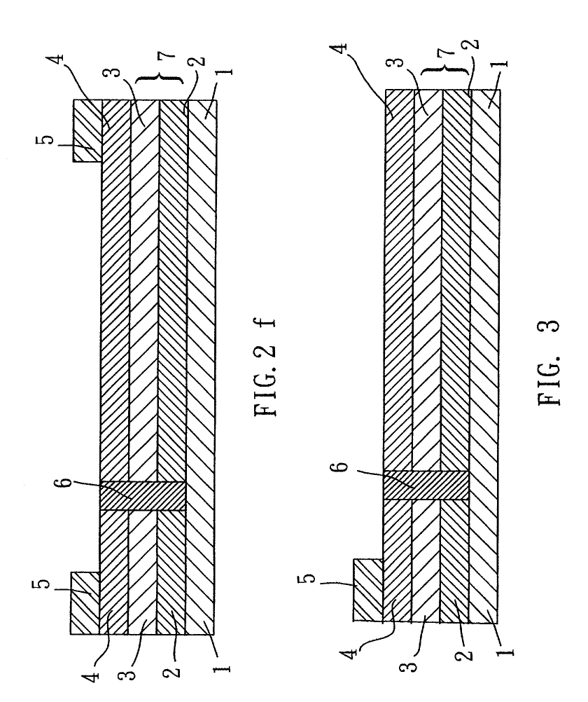

As shown in FIG. 1, it is that the flowchart of a single-chip structure of the SiGe photodetector and the high-speed transistor in this invention. Wherein the photodetector can be either a phototransistor or a photodiode, and the high-speed transistor is a bipolar transistor. Considering both photodetector and high-speed transistor have the similar structure, they can be implemented on the same substrate 1 using the single-chip technology. Furthermore, one separated insulation-layer 6 that was adopted to isolate the photodetector and the high-speed transistor distinctly. It then is formed as a single-chip structure of the SiGe photodetector and the high-speed transistor. For instance, there are two implementation examples can clearly describe the single-chip structure of the phototransistor and the high-speed bipolar transistor in FIG. 2, and another single-chip structure of the photodiode and the high-speed bipolar transistor in FIG. 3.

{The First Implementation Example of This Invention: A Single-Chip Structure of the Phototransistor and the High-Sspeed Bipolar Transistor}

As shown in the FIGS. 2a, 2b, 2c, 2d, 2e, and 2f, it is that the manufacturing process profiles of the first implementation example of a single-chip structure of the phototransistor and the high-speed bipolar transistor. The composite collector layer 7, as shown in FIG. 2a, is built on the substrate 1 that is made of a silicon wafer or a silicon-on-insulator (SOI) wafer. Herein the composite collector layer 7 consists of a collector layer 2 and a photo-absorbing layer 3 which are shown in FIGS. 2b and 2c. Moreover the collector layer 2 and the photo-absorbing layer 3 are sequentially formed on substrate 1. The collector layer 2 of the composite collector layer 7 is made of silicon, but the photo-absorbing layer 3 is made of Si/Si₁₋ₓGeₓ multiple quantum well or superlattice. Herein the scalar X range of Ge in Si/Si₁₋ₓGeₓ is defined as 0<X≦1, it not only owns the ability to absorb the light spectrum with an infrared wavelength, but also improves the light absorption efficiency indeed. The base layer 4 is made of silicon or silicon-germanium, shown in FIG. 2d, which is located on the photo-absorbing layer 3 of the composite collector layer 7. Moreover, the thickness of the base layer 4 is determined by the speed requirement of the high-speed transistor.

As shown in FIG. 2e, the emitter layer 5 is fabricated on the top of the base layer 4 with a specified position. The emitter layer 5 can be designed to partially or completely cover the base layer 4, and this arrangement has two purposes; one is to allow the incident optic signal easily go into the photo-absorbing layer 3 with the option of partial cover of the emitter layer 5, the other is to efficiently reduce the parasitic base resistance and allow the emitter layer 5 to absorb a portion of optic signal with the option of complete cover of the emitter layer 5. The emitter layer 5 and collector layer 2 shall be n-type doping, if the base layer 4 is p-type doping. Oppositely the emitter layer 5 and collector layer 2 shall be p-type doping, if the base layer 4 is n-type doping. Furthermore the photo-absorbing layer 3 of the phototransistor can be an intrinsic (no doping), or n-type, or p-type material. The emitter layer 5 can be made of silicon, poly silicon or silicon-germanium and its thickness is as smaller as 10 nm and goes up to no bounded. A separated insulation-layer 6, as shown in FIG. 2f, which is either made by filling the deep trench with the insulation material or by using the reverse p-n junction. Herein this separated insulation-layer 6 is perpendicularly goes through base layer 4, photo-absorbing layer 3, and collector layer 2, finally connected to the substrate 1.

Conclusively, a single-chip structure of the phototransistor and the high-speed bipolar transistor will be implemented by using aforementioned assembly.

{The Second Implementation Example of This Invention: A Ssingle-Chip Structure of the Photodiode and the High-Sspeed Bipolar Transistor}

As shown in the FIGS. 2a, 2b, 2c, 2d, and FIG. 3, it is that the manufacturing process profiles of the second implementation example about a single-chip structure of the photodiode and the high-speed bipolar transistor. The composite collector layer 7, as shown in FIG. 2a, is built on the substrate 1 that is made of a silicon wafer or a silicon-on-insulator (SOI) wafer. Herein the composite collector layer 7 consists of a collector layer 2 and a photo-absorbing layer 3 which are shown in FIGS. 2b and 2c. Moreover the collector layer 2 and the photo-absorbing layer 3 are sequentially formed on substrate 1. The collector layer 2 of the collector composite layer 7 is made of silicon, but the photo-absorbing layer 3 is made of Si/Si₁₋ₓGeₓ multiple quantum well or superlattice. Herein the X range of Ge in Si/Si₁₋ₓGeₓ is defined as 0<X≦1, it not only owns the ability to absorb the light spectrum with an infrared wavelength, but also improves the light absorption efficiency indeed. The base layer 4 is made of silicon or silicon-germanium, shown in FIG. 2d, which is located on the photo-absorbing layer 3 of the composite collector layer 7.

Moreover, the thickness of the base layer 4 is determined by the speed requirement of the high-speed transistor. As similar as shown in FIG. 3, the emitter layer 5 is formed on the base layer 4 of the high-speed bipolar transistor, but the photodiode has no emitter layer 5. And the photodiode consists of a composite collector layer 7 and a base layer 4. In other words, the photodiode practically consists of p-n or n-p junction type and the emitter layer 5 is applied to the high-speed bipolar transistor only. The structure of the photodiode and the high-speed bipolar transistor, wherein the emitter layer 5 and collector layer 2 shall be n-type doping, if the base layer 4 is the p-type doping. Oppositely the emitter layer 5 and collector layer 2 shall be p-type doping with n-type doping to the base layer 4. Furthermore the photo-absorbing layer 3 of the photodiode can be made of an intrinsic (no doping), n-type, or p-type material.

Referring to the FIG. 3, a separated insulation-layer 6 which is either made by filling the deep trench with the insulation material or by using the reverse p-n junction is located between two terminals of the top-surface of the emitter layer 5 and the base layer 4. Herein this separated insulation-layer 6 is perpendicularly goes through base layer 4, photo-absorbing layer 3, and collector layer 2, finally connected to substrate 1. Conclusively, the separated insulation-layer 6 will separate it into the photodiode and the bipolar transistor, respectively; moreover a single-chip structure of the photodiode and the high-speed bipolar transistor will be implemented by using aforementioned assembly.

In order to particularly define this invention, two selected optimally implementation examples were presented, but it is not limited to any scope of this invention. By all means any related techniques, generic forms, process details, and/or modifications of this invention will be regularly included in the claims of this invention.

What is claimed is:

1. A single-chip structure of silicon germanium photodetectors and high-speed transistors which comprise of:
a substrate;
a phototransistor, which is formed on a side of the substrate;
a high-speed bipolar transistor which is relocated in the opposite side of the phototransistor on substrate; and
a separated insulation-layer, using this layer to separate the phototransistor and the high-speed bipolar transistor, consisting of the above components, a single-chip structure of the phototransistor and the high-speed bipolar transistor can be completely implemented on a same substrate.

2. A single-chip structure of SiGe photodetectors and high-speed transistors, which comprises of claim 1 wherein the substrate can be making from a silicon wafer or a silicon-on-insulator wafer.

3. A single-chip structure of SiGe photodetectors and high-speed transistors, which comprises of claim 1 wherein the phototransistor and high-speed bipolar transistor structure includes:
a composite collector layer consists of a collector layer and a photo-absorbing layer, wherein the photo absorbing layer is formed on the collector layer;
a base layer, located on the composite collector layer;
an emitter layer, formed on the base layer.

4. A single-chip structure of SiGe photodetectors and high-speed transistors, which comprise of claim 1 wherein the separated insulation layer is either made by filling the deep trench with the insulation material or using the reverse p-n junction, it can isolate the photo-detecting zone and the high-speed transistor zone distinctly.

5. The structure of the phototransistor and high-speed bipolar transistor, which comprise of claim 3 wherein the collector layer of the composite collector layer, can choose silicon to make it.

6. The structure of the phototransistor and high-speed bipolar transistor, which comprise of claim 3 wherein the photo-absorbing layer can adopt either Si/Si₁₋ₓGeₓ multiple quantum well or superlattice, the X range of Ge component in Si₁₋ₓGeₓ is defined as 0<X≦1, not only owns the ability to absorb the light spectrum with an infrared wavelength, also improves the light absorption efficiency indeed.

7. The structure of the phototransistor and high-speed bipolar transistor, which comprise of claim 3 wherein the base layer can made of either silicon or silicon germanium, then its thickness is determined by the required speed performance of the high-speed bipolar transistor.

8. The structure of the phototransistor and high-speed bipolar transistor, which comprise of claim 3 wherein the emitter layer can be made of silicon, poly silicon or silicon germanium, its thickness can be as smaller as 10 nm and goes up to unbounded.

9. The structure of the phototransistor and high-speed bipolar transistor, which comprise of claim 3 wherein the emitter and collector layers shall be n-type doping, if the base layer is the p-type doping, the emitter and collector layers shall be p-type doping with n-type doping to the base layer, the photo-absorbing layer of the phototransistor can be made of an intrinsic (no doping), n-type, or p-type material.

10. The structure of the phototransistor and high-speed bipolar transistor, which comprise of claim 3 wherein the emitter layer can be designed to partially or totally cover the base layer.

11. A single-chip structure of SiGe photodetectors and high-speed transistors, which comprise of:
a substrate;
a photodiode, which is formed on a side of the substrate;
a high-speed bipolar transistor which is relocated in the opposite side of the photodiode on substrate; and
a separated insulation layer, using this layer to separate the photodiode and the high-speed bipolar transistor, consisting of the above components, the photodiode and the high-speed bipolar transistor can be completely implemented by using a single-chip structure.

12. A single-chip structure of SiGe photodetectors and high-speed transistors, which comprises of claim 11 wherein the substrate can be choosing from silicon wafer or silicon-on-insulator wafer.

13. A single-chip structure of SiGe photodetectors and high-speed transistors, which comprises of claim 11 wherein the photodiode and high-speed bipolar transistor structure includes:
a composite collector layer consists of a collector layer and a photo-absorbing layer, wherein the photo-absorbing layer is formed on the collector layer;
a base layer, formed on the composite collector layer;
an emitter layer, formed on the base layer of the high-speed bipolar transistor, but the photodiode has no emitter layer.

14. A single-chip structure of SiGe photodetectors and high-speed transistors, which comprises of claim 11 wherein the separated insulation layer is either made by filling the deep trench with the insulation material or using the reverse p-n junction, it can isolate the photo-detecting zone and the high-speed transistor zone distinctly.

15. The structure of the photodiode and high-speed bipolar transistor, which comprises of claim 13 wherein the collector layer of the composite collector layer, can choose silicon to make it.

16. The structure of the photodiode and high-speed bipolar transistor, which comprises of claim 13 wherein the photo-absorbing layer can adopt either Si/Si₁₋ₓGeₓ multiple quantum well or superlattice, the X range of Ge component of Si₁₋ₓGeₓ is defined as 0<X≦1, not only owns the ability to absorb the light spectrum with an infrared wavelength, also improves the light absorption efficiency indeed.

17. The structure of the photodiode and high-speed bipolar transistor, which comprises of claim 13 wherein the base layer can made of either silicon or silicon-germanium, then its thickness is determined by the required speed performance of the high-speed bipolar transistor.

18. The structure of the photodiode and high-speed bipolar transistor, which comprises of claim 13 wherein the emitter layer of the high-speed bipolar transistor can be made of silicon, poly silicon or silicon-germanium, its thickness can be as smaller as 10 nm and goes up to unbounded.

19. The structure of the photodiode and high-speed bipolar transistor, which comprises of claim 13 wherein the emitter and collector layers shall be n-type doping, if the base layer is the p-type doping, oppositely the emitter and collector layers shall be p-type doping with n-type doping to the base layer, the photo-absorbing layer of the phototransistor can be made of an intrinsic (no doping), n-type, or p-type material.
